(19) United States
(12) Patent Application Publication
(10) Pub. No.: US 2025/0129481 A1
(43) Pub. Date: Apr. 24, 2025

(54) MULTIZONE REFLECTOR FOR TEMPERATURE PLANAR NON-UNIFORMITY

(71) Applicant: Applied Materials, Inc., Santa Clara, CA (US)

(72) Inventors: Muhannad Mustafa, Milpitas, CA (US); Aditya Chuttar, Sunnyvale, CA (US)

(73) Assignee: Applied Materials, Inc., Santa Clara, CA (US)

(21) Appl. No.: 18/381,893

(22) Filed: Oct. 19, 2023

(51) Int. Cl. C23C 16/52

(52) U.S. Cl. CPC C23C 16/52

(57) ABSTRACT

Vapor deposition processing chamber temperature control apparatus and vapor deposition processing chambers incorporating the temperature control apparatus are described. The temperature control apparatus has a base plate with a plurality of reflectors arranged in at least two annular zones, each annular zone separated into at least two sector zones. The reflectors are configured to decrease a specific side-to-side temperature non-uniformity profile of a heated substrate support positioned above the base plate in the vapor deposition processing chamber.

### TECHNICAL FIELD

Embodiments of the disclosure generally relate to reflectors for processing chambers. In particular, embodiments of the disclosure relate to multi-zone reflectors for temperature non-uniformity improvement in processing chambers.

### BACKGROUND

During semiconductor device manufacturing, numerous materials are formed on and removed from a substrate to form the underlying devices. Great efforts are generally expended to produce highly uniform material layers and device features. However, distributions in material layer thickness, critical dimension (CD), and the like nonetheless exist across a substrate. As semiconductor device dimensions shrink, such variations in thickness uniformity, CD uniformity, etc., become more difficult to tolerate.

Temperature has a noticeable impact on film thickness variations. In many cases, systemic side-to-side temperature non-uniformity is observed in atomic layer deposition (ALD) and chemical vapor deposition (CVD) processes which cannot be optimized through heater pedestal controls. Often, multi-zone heaters are used which are capable of tuning the radial temperature non-uniformity but do not impact the lateral (or side-to-side) temperature non-uniformity. Multi-pixelated heater solutions are expensive and can be difficult to implement.

Therefore, there is a need in the art for apparatus and methods to decrease the side-to-side planar temperature non-uniformity in semiconductor processing.

### SUMMARY

One or more embodiments of the disclosure are directed to vapor deposition processing chamber temperature control apparatus including: a base plate having a top surface with an opening in a center thereof and an outer peripheral edge; and a plurality of reflectors separated into at least two annular zones, each of the at least two annular zones separated into at least two sector zones, wherein the plurality of reflectors are configured to decrease a specific side-to-side temperature non-uniformity profile of a heated substrate support positioned above the base plate in the vapor deposition processing chamber.

Additional embodiments of the disclosure are directed to vapor deposition processing chamber temperature control apparatus including: a base plate having a top surface with an opening in a center thereof and an outer peripheral edge; and a plurality of reflectors separated into an inner annular zone and an outer annular zone, each of the inner annular zone and outer annular zone separated into two sector zones, the inner annular zone spaced a distance from the outer annular zone to form a ring between the inner annular zone and the outer annular zone where the base plate is exposed, the ring having three openings extending through the base plate, wherein the plurality of reflectors are configured to decrease a specific side-to-side temperature non-uniformity profile of a heated substrate support positioned above the base plate in the vapor deposition processing chamber.

Further embodiments of the disclosure are directed to vapor deposition processing chambers including: a chamber body having a bottom and sidewalls defining an interior volume; a slit valve in the sidewall of the chamber body; a substrate support including a support body and a support shaft, the support body having a support surface, the support shaft extending from a bottom of the support body, the support body including a heating element; and a temperature control apparatus below the support body of the substrate support, the temperature control apparatus including, a base plate having a top surface with an opening in a center thereof and an outer peripheral edge, the support shaft extending through the opening, and a plurality of reflectors separated into an inner annular zone with a first inner sector zone and a second inner sector zone, an outer annular zone with a first outer sector zone and a second outer sector zone, wherein the plurality of reflectors are configured to decrease a specific side-to-side temperature non-uniformity profile of the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional schematic view of a vapor deposition processing chamber with temperature control apparatus according to one or more embodiments of the disclosure;

FIG. 2 illustrates a perspective view of a portion of a vapor deposition processing chamber with temperature control apparatus according to one or more embodiments of the disclosure;

FIGS. 3A through 3E illustrate various embodiments of temperature control apparatus in which there are two annular zones with each annular zone having two sector zones;

FIG. 4A illustrates an embodiment of a temperature control apparatus in which there are two annular zones with each annular zone having three sector zones; and

FIG. 4B illustrates an embodiment of a temperature control apparatus in which there are two annular zones, the inner annular zone having four sector zones and the outer annular zone having two sector zones.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure provide apparatus and methods to increase the wafer side-to-side temperature uniformity through intentional skewed heat loss from the heater pedestal. The skilled artisan will recognize that increasing temperature uniformity and decreasing temperature non-uniformity are used interchangeably. The side-to-side wafer temperature non-uniformity is also referred to as planar non-uniformity or lateral non-uniformity.

One or more embodiments of the disclosure enable fine temperature tuning on the wafer. Some embodiments allow for configuration of temperature profiles based on emissivity and plate arrangement of the reflector plates. Embodiments of the disclosure allow for improving temperature non-uniformity without affecting temperatures in adjacent processing zones within a multi-wafer processing chamber.

One or more embodiments of the disclosure add a bottom base plate with multiple adjustable reflector plates to skew the heat loss from the pedestal. Inner plates and outer plates can be installed on the base plate in various configurations. Inner and outer plates can have differing emissivity (0.1-0.95). Inner and outer plates can be rotated manually to configure the reflector with a predetermined profile to modulate temperature uniformity. In some embodiments, bottom and slit valve purge flow can be employed to prevent back diffusion of process gases to avoid deposition on the reflectors.

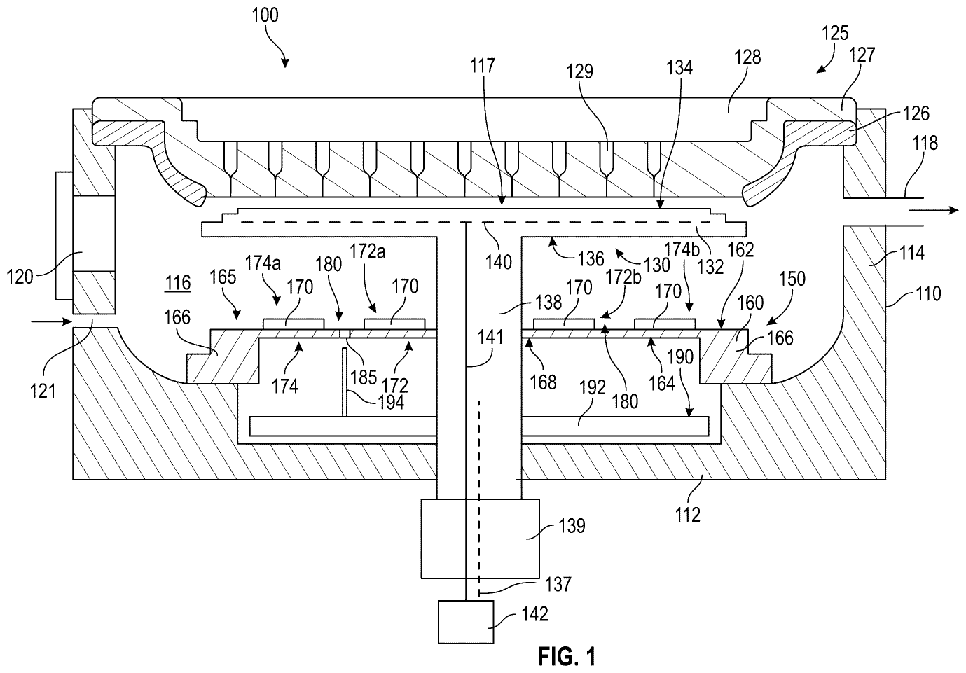

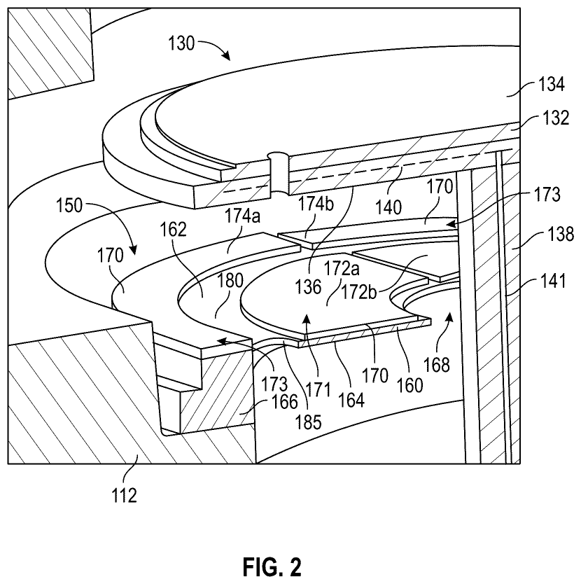

Referring to FIGS. 1 and 2, one or more embodiments of the disclosure are directed to vapor deposition processing chambers 100. FIG. 1 shows a schematic cross-sectional view of a vapor deposition processing chamber 100 according to one or more embodiment of the disclosure. FIG. 2 shows a portion of vapor deposition processing chamber 100 according to one or more embodiment of the disclosure. The vapor deposition processing chambers 100 comprises a chamber body 110 with a bottom 112 and sidewalls 114. A lid 125 is on the sidewalls 114 and, with the chamber body, defines the interior volume 116 of the vapor deposition processing chambers 100. The lid 125 illustrated in FIG. 1 includes a purge ring 126, with a showerhead 127 and backing plate 128. A gas source (not shown) can be connected to the lid 125 so that a gas can flow through the backing plate 128 into a plenum (not shown) between the backing plate 128 and the showerhead 127 and then through apertures 129 in the showerhead 127 into the interior volume 116 of the vapor deposition processing chambers 100. In particular, a gas may flow through the showerhead 127 into the process region 117 adjacent the front surface of the showerhead 127. The skilled artisan will recognize that the lid 125 illustrated in FIG. 1 is merely representative of one possible process chamber configuration and should not be taken as limiting the scope of the disclosure. In some embodiments, the lid 125 encloses the interior volume 116 of the vapor deposition processing chambers 100 and the gas flows are through the sidewalls 114 of the chamber body 110 into the process region 117 and interior volume 116 of the vapor deposition processing chambers 100. In some embodiments, the interior volume 116 is connected to an exhaust 118 to allow the interior volume 116 and/or process region 117 to be purged of process gases. The skilled artisan will be familiar with the apparatus associated with the exhaust 118 including, but not limited to, foreline connections, vacuum pump connections, etc.

A slit valve 120 is formed in the sidewalls 114 of the chamber body 110. The slit valve 120 can be any suitable valve or component capable of opening and closing to allow a wafer to be moved into and out of the interior volume 116 while being able to maintain pressure conditions within the interior volume 116 during processing.

A substrate support 130 is located within the interior volume 116 of the chamber body 110. The substrate support 130 comprises a support body 132 and a support shaft 138. The support body 132 has a support surface 134 configured to hold a wafer during processing. The support shaft 138 extends from a bottom 136 of the support body 132 and, in the illustrated embodiment, passes through the bottom 112 of the chamber body 110. The support shaft 138 can have one or more motors 139 attached thereto in order to move the substrate support 130 up and down and to rotate the substrate support 130 around a central axis 137.

The support body 132 of some embodiments comprises a heating element 140 within the thickness of the support body 132. The heating element 140 can be any suitable heater known to the skilled artisan. For example, in the illustrated embodiment, the heating element 140 comprises a resistive heater connected to an external heating power source 142 through a heating power line 141. In some embodiments, the support body 132 comprises an electrostatic chuck (not shown) which can be used to hold a wafer in position on the support surface 134 during processing. The skilled artisan will be familiar with suitable electrostatic chucks and the associated components used in conjunction with the electrostatic chucks. In some embodiments, the support body 132 comprises one or more vacuum or purge gas ports with openings in the support surface 134 and connections to suitable gas sources or vacuum sources through the support shaft 138. The vacuum or purge gas ports can be used to chuck a wafer to the support surface 134 for processing, prevent backside deposition on the wafer during processing, provide backside purge for dechucking, etc. The skilled artisan will be familiar with the various components and arrangements associated with the use of purge gas and vacuum ports in the support surface 134.

Embodiments of the disclosure add a bottom base plate to the processing chamber with multiple adjustable reflector plates configured to skew the heat loss from the substrate support. Inner plates and outer plates installed on the base plate can have different emissivity (e.g., 0.1-0.95). Inner and outer plates can be rotated manually to configure the reflector with a predetermined profile to modulate temperature uniformity. Bottom and slit valve purge flow 121 can be used to prevent back diffusion of process gases and to avoid deposition on the reflectors. Some embodiments of the disclosure advantageously provide apparatus and methods to increase temperature uniformity on the substrate support and wafer. Additionally, in multi-zone processing chambers, embodiments of the disclosure advantageously allow for the increasing of temperature uniformity on the substrate support and wafer without affecting the temperature uniformity of adjacent substrate supports in adjacent processing zones.

A temperature control apparatus 150 is positioned below the support body 132 of the substrate support 130 within the interior volume 116 of the vapor deposition processing chambers 100. The temperature control apparatus 150 comprises a base plate 160 with a top surface 162 and a bottom surface 164 that define a thickness of the base plate 160. In some embodiments, the base plate 160 includes one or more standoffs 166 located at or near the outer peripheral edge 165 of the base plate 160. The one or more standoffs 166 are configured to support the base plate 160 on the bottom 112 of the chamber body 110 and create space between the bottom 112 of the chamber body 110 and the bottom surface 164 of the base plate 160 of the temperature control apparatus 150.

The base plate 160 has an opening 168 in the center thereof. The opening 168 is sized to allow the support shaft 138 of the substrate support 130 to extend through the base plate 160 without contacting the base plate 160.

The temperature control apparatus 150 includes a plurality of reflectors 170 on the top surface 162 of the base plate 160. The plurality of reflectors 170 can be separate components affixed to the top surface 162 of the base plate 160 or can be a part of the top surface 162 of the base plate 160. For example, in some embodiments, the plurality of reflectors 170 comprise individual reflector pieces that are affixed to the top surface 162 by any suitable fastener including, but not limited to, removable fasteners like screws and bolts, or permanent fasteners like welding. The plurality of reflectors 170 are configured to decrease a specific side-to-side temperature non-uniformity profile of a heated substrate support 130 positioned above the base plate 160 in the vapor deposition processing chamber 100.

The plurality of reflectors 170 are separated into annular zones 171 and sector zones 173. The annular zones 171 are positioned around the opening 168 in the base plate 160 at different radial distances from the opening 168. In some embodiments, the annular zones 171 are concentric with the opening 168. The sector zones 173 are measured at different angles relative to a fixed direction, for example, the slit valve 120. Each of the annular zones 171 independently comprise one or more sectors zones 173. In some embodiments, each of the annular zones 171 independently comprises two or more sector zones 173. In some embodiments, each of the annular zones 171 comprise two sector zones 173.

For example, in the embodiment illustrated in FIGS. 1 through 3E, the temperature control apparatus 150 comprises two annular zones 171; an inner annular zone 172 and an outer annular zone 174. The inner annular zone 172 has a first inner sector zone 172a and a second inner sector zone 172b. The outer annular zone 174 has a first outer sector zone 174a and a second outer sector zone 174b.

In some embodiments, the two annular zones 171 are spaced a distance apart. For example, the inner annular zone 172 is spaced a distance from the outer annular zone 174 to form a ring 180 between the inner annular zone 172 and the outer annular zone 174 where the top surface 162 of the base plate 160 is exposed. In some embodiments, the ring 180 has a width (measured along a radius of the temperature control apparatus 150 from the opening 168) in the range of 5 mm to 100 mm, or in the range of 10 mm to 50 mm, or in the range of 20 mm to 40 mm.

In some embodiments, the ring 180 between the inner annular zone 172 and the outer annular zone 174 has one or more lift pin openings 185 extending through the base plate 160. In some embodiments, the ring 180 has three lift pin openings 185 extending through the base plate 160. In some embodiments, as shown in FIG. 1, the vapor deposition processing chambers 100 further comprises a lift pin assembly 190 comprising a lift pin base 192 and at least three lift pins 194. The lift pins 194 are spaced equidistant around a central axis of the lift pin base 192. The cross-sectional schematic view of FIG. 1 shows a single lift pin 194 because the other two lift pins are outside the plane of the cross-section.

The plurality of reflectors 170 are configured to have different emissivities so that heat radiating from the bottom of the substrate support 130 is preferentially absorbed and/or reflected back to the substrate support 130. For example, in some embodiments, the plurality of reflectors 170 are configured so that reflectors positioned below colder portions of the substrate support 130 have a lower emissivity than reflectors position below warmer portions of the substrate support 130.

The emissivity of the plurality of reflectors 170, according to some embodiments, is independently in the range of 0.1 to 0.95. Lower emissivity values are indicative of a more reflective material than higher emissivity values which indicate a more absorbent material. In some embodiments, the emissivity of the plurality of reflectors 170 is independently in the range of 0.2 to 0.9, or in the range of 0.25 to 0.85, or in the range of 0.3 to 0.8, or in the range of 0.35 to 0.75. In some embodiments, the plurality of reflectors 170 are separated in high emissivity and low emissivity reflectors, where high emissivity is greater than or equal to 0.6, 0.65, 0.7, 0.75 or 0.8, and low emissivity is less than or equal to 0.5, 0.45, 0.4, 0.35, 0.3, 0.25 or 0.2. The emissivity of the plurality of reflectors 170 can be based on the material of construction of the reflectors, the surface characteristic (e.g., roughness) of the reflectors, or through other modifications known to the skilled artisan.

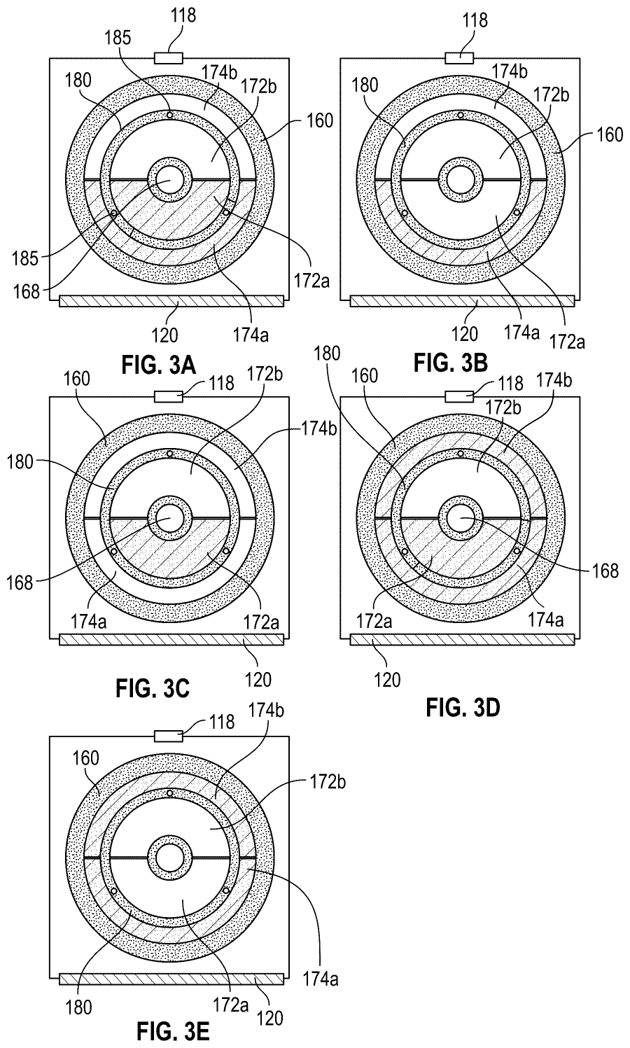

Referring to FIGS. 3A through 3E, the inner annular zone 172 is separated into a first sector zone 172a and a second sector zone 172b. The outer annular zone 174 is separated into a first sector zone 174a and a second sector zone 174b.

In some embodiments, the first sector zone 172a of the inner annular zone 172 has a first inner emissivity, and a second sector zone 172b of the inner annular zone 172 has a second inner emissivity. The first inner emissivity of some embodiments is different than the second inner emissivity. In some embodiments, the first inner emissivity and the second inner emissivity are the same.

In some embodiments, the first sector zone 174a of the outer annular zone 174 has a first outer emissivity, and a second sector zone 174b of the outer annular zone 174 has a second outer emissivity. In some embodiments, the first outer emissivity and the second outer emissivity are different. In some embodiments, the first outer emissivity and the second outer emissivity are the same.

The shape and sizes of the reflectors in the individual sector zones can be configured to correct for the specific side-to-side temperature variations in the substrate support. In some embodiments, each of the sector zones of the inner annular zone 172 have substantially the same shape. As used in this manner, the term “substantially the same” means that the overall width and ends of the sectors are within ±10%, ±5% or ±2% of each other. In the embodiments illustrated in FIGS. 3A through 3E, the shape of the first sector zone 172a and second sector zone 172b of the inner annular zone 172 are substantially the same. In some embodiments, each of the sector zones of the outer annular zone 174 have substantially the same shape. In the embodiments illustrated in FIGS. 3A through 3E, the shape of the first sector zone 174a and second sector zone 174b of the outer annular zone 174 are substantially the same.

In the embodiments illustrated in FIGS. 3A through 3E, each of the first sector zones and second sector zones are aligned relative to the slit valve 120. However, the skilled artisan will recognize that this is merely representative of one possible configuration and should not be taken as limiting the scope of the disclosure. In some embodiments, the first sector zone 172a of the inner annular zone 172 is aligned with the first sector zone 174a of the outer annular zone 174. As used in this manner, the term “aligned” means that the centers of the reflectors in the stated zones are aligned relative to the central axis of the temperature control apparatus 150. In some embodiments, the second sector zone 172b of the inner annular zone 172 is aligned with the second sector zone 174b of the outer annular zone 174.

FIG. 3A shows an embodiment of the disclosure in which the first sector zone 172a of the inner annular zone 172 and the first sector zone 174a of the outer annular zone 174 have substantially the same emissivity, and the second sector zone 172b of the inner annular zone 172 and the second sector zone 174b of the outer annular zone 174 have substantially the same emissivity. As used in this manner, the term “substantially the same emissivity” means that the emissivities of the stated reflectors or stated zones is within ±0.1, or within ±0.05.

In some embodiments, the first sector zone 172a of the inner annular zone 172 and the second sector zone 172b of the inner annular zone 172 each independently have an emissivity greater than or equal to 0.75, and the second sector zone 172b of the inner annular zone 172 and the second sector zone 174b of the outer annular zone 174 each independently have an emissivity less than or equal to 0.5.

In some embodiments, the first sector zone 172a of the inner annular zone 172 and the first sector zone 174a of the outer annular zone 174 of the temperature control apparatus 150 are positioned adjacent the slit valve 120 in the sidewall 114 of the chamber body 110 and have an emissivity >0.75, and the second sector zone of the inner annular zone and the second sector zone of the outer annular zone have an emissivity <0.75.

FIG. 3B illustrates an embodiment of a temperature control apparatus 150 in which the first sector zone 172a and second sector zone 172b of the inner annular zone 172 and the second sector zone 174b of the outer annular zone 174 have substantially the same emissivity. The first sector zone 174a of the outer annular zone 174, adjacent to the slit valve 120, has a different emissivity.

FIG. 3C illustrates an embodiment of a temperature control apparatus 150 in which the second sector zone 172b of the inner annular zone 172 and the first sector zone 174a and outer annular zone 174 of the outer annular zone 174 have substantially the same emissivity. The first sector zone 172a of the inner annular zone 172, on the side of the opening 168 adjacent the slit valve 120, has a different emissivity.

FIG. 3D illustrates an embodiment of a temperature control apparatus 150 in which the first sector zone 172a of the inner annular zone 172 and the first sector zone 174a and second sector zone 174b of the outer annular zone 174 have substantially the same emissivity. The second sector zone 172b of the inner annular zone 172, on the side of the opening 168 opposite the slit valve 120, has a different emissivity.

FIG. 3E illustrates an embodiment of a temperature control apparatus 150 in which the first sector zone 172a and second sector zone 172b of the inner annular zone 172 have substantially the same emissivity, and the first sector zone 174a and the second sector zone 174b of the outer annular zone 174 have substantially the same emissivity.

While the illustrated embodiments show two annular zones 171, the skilled artisan will recognize that there can be more than two annular zones 171. In some embodiments, there are more than two annular zones 171 and there is a ring 180 between two of the annular zones, or separate rings between each of the annular zones.

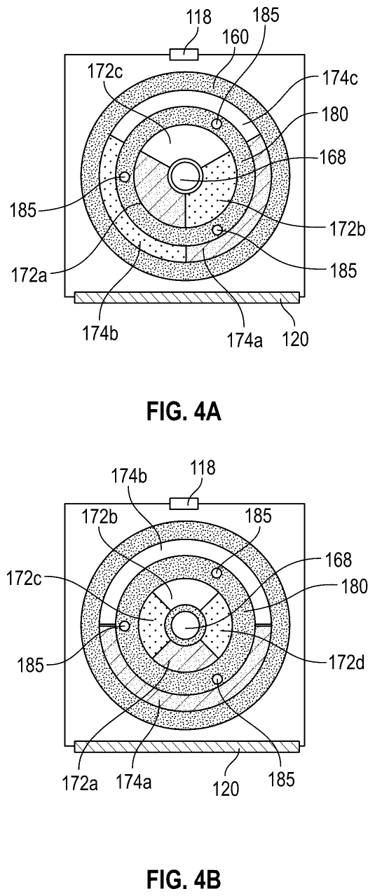

The embodiments illustrated in FIGS. 3A through 3E show two annular zones 171, each with two sector zones 173. The skilled artisan will recognize that this is merely one possible configuration and should not be taken as limiting the scope of the disclosure. In some embodiments, finer control of the temperature uniformity of the substrate support can be performed using more than two annular zones and/or more than two sector zones. FIG. 4A illustrates an embodiment in which each of the inner annular zone 172 and the outer annular zone 174 have three sector zones 173. In the illustrated embodiment, the first sector zone 172a of the inner annular zone 172 and the first sector zone 174a of the outer annular zone 174 have a first emissivity, the second sector zone 172b of the inner annular zone 172 and the second sector zone 174b of the outer annular zone 174 have a second emissivity different from the first emissivity, and the third sector zone 172c of the inner annular zone 172 and the third sector zone 174c of the outer annular zone 174 have a third emissivity different from the first emissivity and the second emissivity. The first sector zone 172a of the inner annular zone 172 and the first sector zone 174a of the outer annular zone 174 of the illustrated embodiment are on opposite sides of an imaginary line extending from the center of the opening 168 normal to the slit valve 120. Similarly, the second sector zone 172b of the inner annular zone 172 and the second sector zone 174b of the outer annular zone 174 are on opposite sides of the imaginary line extending from the center of the opening 168 normal to the slit valve 120. The skilled artisan will recognize that the angular orientation of the individual reflectors can be arranged to meet the specific side-to-side temperature variations.

FIG. 4B illustrates another embodiment of the disclosure in which the inner annular zone 172 is split into four sector zones 173 while the outer annular zone 174 is split into two sector zones 173. In this embodiment, the first sector zone 172a of the inner annular zone 172 and the first sector zone 174a of the outer annular zone 174 have a first emissivity, and are centered on the imaginary line extending from the center of the opening 168 normal to the slit valve 120. The second sector zone 172b of the inner annular zone 172 and the second sector zone 174b of the outer annular zone 174 have a second emissivity different from the first emissivity, and are centered on the imaginary line extending normal to the slit valve 120 through the center of the opening 168 on opposite sides of the opening 168 relative to the reflectors with the first emissivity. The third sector zone 172c and fourth sector zone 172d of the inner annular zone 172 have a third emissivity different from the first emissivity and the second emissivity. The third sector zone 172c and fourth sector zone 172d of the inner annular zone 172 are positioned on opposite sides of the opening 168 between the first sector zone 172a and second sector zone 172b of the inner annular zone 172.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A vapor deposition processing chamber temperature control apparatus comprising:
a base plate having a top surface with an opening in a center thereof and an outer peripheral edge; and
a plurality of reflectors separated into at least two annular zones, each of the at least two annular zones separated into at least two sector zones,
wherein the plurality of reflectors are configured to decrease a specific side-to-side temperature non-uniformity profile of a heated substrate support positioned above the base plate in the vapor deposition processing chamber.

2. The apparatus of claim 1, wherein there are two annular zones.

3. The apparatus of claim 2, wherein the two annular zones comprise an inner annular zone and an outer annular zone, the inner annular zone spaced a distance from the outer annular zone to form a ring between the inner annular zone and the outer annular zone where the base plate is exposed.

4. The apparatus of claim 3, wherein the ring between the inner annular zone and the outer annular zone has three lift pin openings extending through the base plate.

5. The apparatus of claim 3, wherein the wherein each of the inner annular zone and the outer annular zone have two sector zones.

6. The apparatus of claim 5, wherein a first sector zone of the inner annular zone has a first inner emissivity, and a second sector zone of the inner annular zone has a second inner emissivity.

7. The apparatus of claim 6, wherein the first inner emissivity and the second inner emissivity are different.

8. The reflector plate of claim 5, wherein a first sector of the outer annular zone has a first outer emissivity, and a second sector zone of the outer annular zone has a second outer emissivity.

9. The apparatus of claim 8, wherein the first outer emissivity and the second outer emissivity are different.

10. The apparatus of claim 5, wherein each of the sector zones of the inner annular zone have substantially the same shape.

11. The apparatus of claim 5, wherein each of the sector zones of the outer annular zone have substantially the same shape.

12. The apparatus of claim 5, wherein a first sector zone of the inner annular zone is aligned with a first sector zone of the outer annular zone.

13. The apparatus of claim 12, wherein the second sector zone of the inner annular zone is aligned with the second sector zone of the outer annular zone.

14. The apparatus of claim 13, wherein the first sector zone of the inner annular zone and the first sector zone of the outer annular zone have substantially the same emissivity.

15. The apparatus of claim 14, wherein the second sector zone of the inner annular zone and the second sector zone of the outer annular zone have substantially the same emissivity.

16. The apparatus of claim 15, wherein the first sector zone of the inner annular zone and the first sector zone of the outer annular zone have an emissivity >0.75, and the second sector zone of the inner annular zone and the second sector zone of the outer annular zone have an emissivity <0.5.

17. A vapor deposition processing chamber temperature control apparatus comprising:
a base plate having a top surface with an opening in a center thereof and an outer peripheral edge; and
a plurality of reflectors separated into an inner annular zone and an outer annular zone, each of the inner annular zone and outer annular zone separated into two sector zones, the inner annular zone spaced a distance from the outer annular zone to form a ring between the inner annular zone and the outer annular zone where the base plate is exposed, the ring having three openings extending through the base plate,
wherein the plurality of reflectors are configured to decrease a specific side-to-side temperature non-uniformity profile of a heated substrate support positioned above the base plate in the vapor deposition processing chamber.

18. A vapor deposition processing chamber comprising:
a chamber body having a bottom and sidewalls defining an interior volume;
a slit valve in the sidewall of the chamber body;
a substrate support comprising a support body and a support shaft, the support body having a support surface, the support shaft extending from a bottom of the support body, the support body comprising a heating element; and
a temperature control apparatus below the support body of the substrate support, the temperature control apparatus comprising,
a base plate having a top surface with an opening in a center thereof and an outer peripheral edge, the support shaft extending through the opening, and
a plurality of reflectors separated into an inner annular zone with a first inner sector zone and a second inner sector zone, an outer annular zone with a first outer sector zone and a second outer sector zone,
wherein the plurality of reflectors are configured to decrease a specific side-to-side temperature non-uniformity profile of the substrate support.

19. The processing chamber of claim 18, wherein the first sector zone of the inner annular zone and the first sector zone of the outer annular zone of the temperature control apparatus are positioned adjacent the slit valve in the sidewall of the chamber body and have an emissivity >0.75, and the second sector zone of the inner annular zone and the second sector zone of the outer annular zone have an emissivity <0.75.

20. The processing chamber of claim 19, wherein the inner annular zone is spaced a distance from the outer annular zone to form a ring between the inner annular zone and the outer annular zone where the base plate is exposed, and the base plate comprises three openings in the ring.
